(19) United States
(12) Patent Application Publication
(10) Pub. No.: US 2014/0151571 A1
(43) Pub. Date: Jun. 5, 2014

(54) CHARGED PARTICLE BEAM LENS AND EXPOSURE APPARATUS USING THE SAME

(71) Applicants: Takahisa Kato, Brookline, MA (US); Yutaka Setomoto, Tokyo (JP)

(72) Inventors: Takahisa Kato, Brookline, MA (US); Yutaka Setomoto, Tokyo (JP)

(73) Assignee: CANON KABUSHIKI KAISHA, Tokyo (JP)

(21) Appl. No.: 14/005,175

(22) PCT Filed: Mar. 14, 2012
(86) PCT No.: PCT/JP2012/001777

§ 371 Date: Feb. 24, 2014

(30) Foreign Application Priority Data
Mar. 15, 2011 (JP) 2011-056812

(51) Int. Cl. H01J 37/12

(52) U.S. Cl. CPC H01J 37/12
USPC 250/396 R

(57) ABSTRACT

In a charged particle beam lens according to the present invention, the orientations of through-holes formed in electrodes and precision of forming the through-holes are determined in accordance with the degree of influences of the surfaces of the electrodes on the aberration of the lens.

### TECHNICAL FIELD

The present invention relates to the technical field of electron optical systems that are used in apparatuses using a charged particle beam such as an electron beam. In particular, the present invention relates to an electron optical system that is used in an exposure apparatus. In the present invention, the term “light” refers not only to visible light but also to electromagnetic radiation such as an electron beam or the like.

### BACKGROUND ART

In the production of semiconductor devices, electron beam exposure technology is a promising lithography technology that enables exposure of a fine pattern with a width of 0.1 micrometers or smaller. In electron beam exposure apparatuses, an electron optical element is used to control optical characteristics of an electron beam. Electron lenses are classified into an electromagnetic type and an electrostatic type. The structure of an electrostatic electron lens is simpler than that of an electromagnetic electron lens because an electrostatic electron lens does not have a coil core. Therefore, the electrostatic type is advantageous in reduction in size. Regarding the electron beam exposure technology, multi-beam systems, which form a pattern by simultaneously using a plurality of electron beams instead of using a mask, have been proposed. A multi-beam system includes an electron lens array in which electron lenses are arranged one dimensionally or two dimensionally. In the electron beam lithography technology, the limit of microfabrication is not determined by the diffraction limit of an electron beam but by optical aberrations of an electron optical element. Therefore, it is important to realize an electron optical element having small aberrations.

For example, PTL 1 describes an electrostatic lens apparatus including a plurality of electrode substrates each having an opening disposed in a plane perpendicular to an optical axis and the electrode substrates are assembled while adjusting the positions of the openings.

### CITATION LIST

### Patent Literature

PTL 1: Japanese Patent Laid-Open No. 2007-019194

### SUMMARY OF INVENTION

### Technical Problem

An electrostatic charged particle beam lens has a structure simpler than that of an electromagnetic lens. However, optical aberrations of an electrostatic charged particle beam lens are highly sensitive to a fabrication error of a through-hole of the lens. In particular, when the opening is circular, astigmatism of the lens is sensitive to the symmetry of the shape of the through-hole, such as the circularity (deviation of a circular shape from a perfect circle) of the opening. An electron beam that is converged under the influence of an asymmetric through-hole has astigmatism or another high order aberration.

In particular, this problem is important when a plurality of electron beams having different astigmatisms is used, because such astigmatisms cannot be corrected by using an ordinary stigmator.

According to a first aspect of the present invention, an electrostatic charged particle beam lens includes a first flat plate including a first surface having a normal line extending in a direction of an optical axis and a second surface opposite to the first surface, a second flat plate including a third surface facing the second surface and a fourth surface opposite to the third surface, and a third flat plate including a fifth surface facing the fourth surface and a sixth surface opposite to the third surface. The first flat plate has a first through-hole extending therethrough from the first surface to the second surface, the second flat plate has a second through-hole extending therethrough from the third surface to the fourth surface, and the third flat plate has a third through-hole extending therethrough from the fifth surface to the sixth surface. The first through-hole, the second through-hole, and the third through-hole are arranged so that a charged particle beam is allowed to successively pass therethrough. When an opening cross section is defined as a cross section of one of the through-holes taken along a plane perpendicular to the optical axis and an incircle and a circumcircle are respectively defined as two concentric circles having a smaller radius and a larger radius between which the opening cross section is disposed and having the smallest difference in the radii, a difference in the radii of the incircle and the circumcircle of the opening cross section at each of the first surface and the sixth surface is larger than a difference in the radii of the incircle and the circumcircle of the opening cross section at each of the second surface, the third surface, the fourth surface, and the fifth surface.

According to a second aspect of the present invention, an electrostatic charged particle beam lens includes a first flat plate including a first surface having a normal line extending in a direction of an optical axis and a second surface opposite to the first surface, a second flat plate including a third surface facing the second surface and a fourth surface opposite to the third surface, and a third flat plate including a fifth surface facing the fourth surface and a sixth surface opposite to the third surface. The first flat plate has a first through-hole extending therethrough from the first surface to the second surface, the second flat plate has a second through-hole extending therethrough from the third surface to the fourth surface, and the third flat plate has a third through-hole extending therethrough from the fifth surface to the sixth surface. The first through-hole, the second through-hole, and the third through-hole are arranged so that a charged particle beam is allowed to successively pass therethrough. When an opening cross section is defined as a cross section of one of the through-holes taken along a plane perpendicular to the optical axis, a value of circularity of the opening cross section at each of the first surface and the sixth surface is larger than a value of circularity of the opening cross section at each of the second surface, the third surface, the fourth surface, and the fifth surface.

### Advantageous Effects of Invention

With the charged particle beam lens according to the present invention, an opening cross section having a large fabrication error may be used as a surface that is most unlikely to influence the aberration of the lens, so that the number of positions at which high precision fabrication is required or the number of fabrication steps can be reduced and the yield can be increased.

### BRIEF DESCRIPTION OF DRAWINGS

FIG. 1A is a sectional view of a charged particle beam lens according to a first embodiment of the present invention.

FIG. 1B is a top view of the charged particle beam lens according to the first embodiment of the present invention.

FIG. 2 is a conceptual diagram illustrating a convergence effect of an electrostatic charged particle beam lens.

FIG. 3A is a sectional view of a through-hole that is formed from both sides.

FIG. 3B is a sectional view of a through-hole that is formed from one side.

FIG. 4A is a conceptual diagram illustrating the definition of the circularity of an opening cross section.

FIG. 4B is a conceptual diagram illustrating the definition of the circularity of an opening cross section.

FIG. 4C is a conceptual diagram illustrating the definition of the circularity of an opening cross section.

FIG. 4D is a conceptual diagram illustrating the definition of the circularity of an opening cross section.

FIG. 4E is a conceptual diagram illustrating the definition of the circularity of an opening cross section.

FIG. 4F is a conceptual diagram illustrating the definition of the circularity of an opening cross section.

FIG. 5A is a sectional view of a charged particle beam lens according to a second embodiment of the present invention.

FIG. 5B is a table illustrating the aberration of the second embodiment of the present invention.

FIG. 5C is a table illustrating the aberration of the second embodiment of the present invention.

FIG. 5D is a table illustrating the aberration of the second embodiment of the present invention.

FIG. 6 is a sectional view of a charged particle beam lens array according to a third embodiment of the present invention.

FIG. 7 is a conceptual diagram illustrating an exposure apparatus according to a fourth embodiment of the present invention.

### DESCRIPTION OF EMBODIMENTS

In the present invention, the terms “first surface” and “second surface” respectively refer to one of the surfaces (front surface) and the other surface (back surface) of an electrode of a charged particle beam lens according the present invention. Likewise, in the present invention, the third surface and the fourth surface, and the fifth surface and the sixth surface respectively have the relationship described above. In the present invention, the term “surfaces that face each other” refers to surfaces of electrodes, each of which including two or more flat plates, that face each other when the electrodes are disposed with predetermined intervals therebetween.

In the present invention, the phrase “through-holes extending from the X-th surface to the Y-th surface (where X and Y are integers in the range from 1 to 6)” refers to a through-hole through which the X-th surface and the Y-th surface are connected to each other. It does not matter in which direction the through-hole is formed. That is, the through-hole may be formed from the X-th surface, from the Y-th surface, or from both of these surfaces.

In the present invention, a first potential, a second potential, and a third potential are the potentials that are applied to respective electrodes included in a charged particle beam lens according to the present invention. The first potential is applied to the first surface and the second surface, the second potential is applied to the third surface and the fourth surface, and the third potential is applied to the fifth surface and the sixth surface.

According to the present invention, an electrostatic charged particle beam lens includes a first flat plate including a first surface having a normal line extending in a direction of an optical axis and a second surface opposite to the first surface; a second flat plate including a third surface facing the second surface and a fourth surface opposite to the third surface; and a third flat plate including a fifth surface facing the fourth surface and a sixth surface opposite to the third surface. The first flat plate has a first through-hole extending therethrough from the first surface to the second surface, the second flat plate has a second through-hole extending therethrough from the third surface to the fourth surface, and the third flat plate has a third through-hole extending therethrough from the fifth surface to the sixth surface. The first through-hole, the second through-hole, and the third through-hole are arranged so that a charged particle beam is allowed to successively pass therethrough. When an opening cross section is defined as a cross section of the through-hole taken along a plane perpendicular to the optical axis and an incircle and a circumcircle are respectively defined as two concentric circles having a smaller radius and a larger radius between which the opening cross section is disposed and having the smallest difference in the radii, each of the difference in the radii of the incircle and the circumcircle of the opening cross section in a first surface and in the sixth surface are larger than the difference in the radii of the incircle and the circumcircle of the opening cross section in the second surface, the third surface, the fourth surface, an the fifth surface.

With the charged particle beam lens according to the present invention, an opening cross section having a large fabrication error may be used as a surface that is most unlikely to influence the aberration of the lens, so that the number of positions at which high precision fabrication is required or the number of fabrication steps can be reduced and the yield can be increased.

With the charged particle beam lens according to the present invention, in the case where the lens is used for a charged particle beam having a negative charge, an opening cross section having a large fabrication error may be formed in a surface that has a small influence on the aberration of the lens, and an opening cross section having a small fabrication error may be formed only in a portion having a large influence on the aberration of the lens. Thus, the number of positions at which high-cost and high-precision fabrication is necessary and the number of fabrication steps can be decreased and thereby the yield can be increased. In particular, due to the relationship between potentials in the present invention, the convergence effect relative to the strength of an electric field is appropriately increased.

With the charged particle beam lens according to the present invention, in the case where the lens is used for a charged particle beam having a positive charge, an opening cross section having a large fabrication error may be formed in a surface that has a small influence on the aberration of the lens, and an opening cross section having a small fabrication error may be formed only in a portion having a large influence on the aberration of the lens. Thus, the number of positions at which high-cost and high-precision fabrication is necessary and the number of fabrication steps can be decreased and thereby the yield can be increased. In particular, due to the relationship between potentials in the present invention, the convergence effect relative to the strength of an electric field is appropriately increased.

With the charged particle beam lens according to the present invention, a step of forming through holes in surfaces for which high precision is required may be performed independently of a step of forming through holes in other surfaces. By independently performing these steps, fine and high precision through-holes can be formed by using semiconductor manufacturing technologies, while improving controllability of etching conditions and the yield. In particular, an electrode having a finer through-hole can be formed with high precision by using microfabrication technologies, such as photolithography or dry etching, and wafer bonding through silicon wafers having high degree of flatness. Thus, an electrostatic charged particle beam lens having a through-hole that has a diameter in the order of several tens of micrometers and a circularity in the order of nanometers can be formed. Because the steps described above are performed independently from each other, the opening cross sections can be selectively used at appropriate positions in accordance with the shape errors of the opening cross sections, whereby the yield of high-precision and high-cost fabrication can be increased.

The charged particle beam lens according to the present invention may be formed as a charged particle beam lens array including an electrode having a plurality of through-holes. Because the opening cross sections having appropriate fabrication errors can be disposed in accordance with the contributions to the aberration of the lens, influence of the variation in the circularities of the opening cross sections of individual lenses of the lens array on the aberration can be reduced. In the case of a lens array, it is difficult to correct the circularity of each of the individual lenses because the circularity has a random error. However, because variation in the circularity of the opening cross section can be reduced by using the present invention, necessity for individual correction can be eliminated or considerably reduced even for a large-scale lens array. Moreover, when an electrode having a bonding structure is used, variation in the opening cross sections can be sufficiently reduced. If the alignment precision of bonding is low, displacement between the through-holes occurs. However, this displacement can be easily corrected because it is a systematic displacement in the entirety of the lens array. Therefore, this structure is appropriate for a large-scale lens array.

An exposure apparatus according to the present invention includes the charged particle beam lens according to the present invention having a small aberration, so that the exposure apparatus can form a fine pattern with high precision.

The exposure apparatus according to the present invention may use a plurality of charged particle beams by using the charged particle beam lens according to the present invention having a small aberration, so that the exposure apparatus can form a fine pattern with high precision and high speed.

### Embodiments

Hereinafter, embodiments of the present invention will be described in detail. However, the present invention is not limited to these embodiments.

### First Embodiment

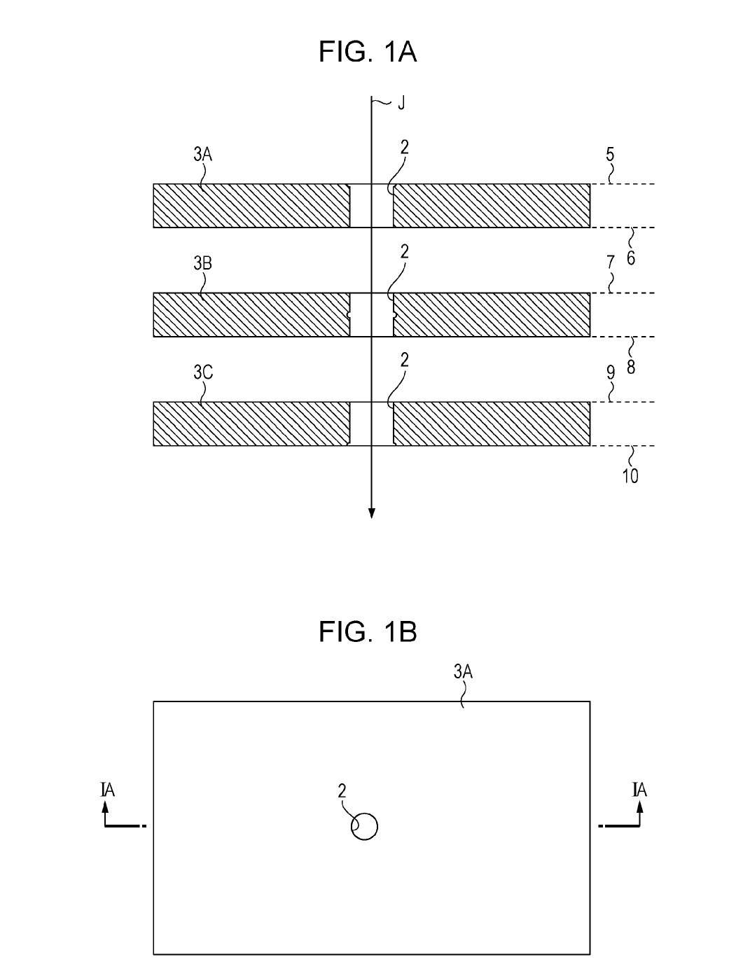

Referring to FIGS. 1A to 4F, a first embodiment of the present invention will be described.

FIG. 1A is a sectional view of a charged particle beam lens according to the present invention taken along line IA-IA of FIG. 1B. FIG. 1B is a top view of the charged particle beam lens. A length in the direction of an optical axis J will be referred to as a thickness.

As illustrated in FIG. 1A, the charged particle beam lens according to the present invention includes three electrodes 3A, 3B, and 3C. Each of the three electrodes is a flat plate having the optical axis J as a normal line and including a first surface and a second surface opposite to the first surface. The three electrodes are electrically insulated from one another. The first surface is typically the front surface of the electrode, and the second surface is typically the back surface of the electrode. Here, the terms “front” and “back” are used only to denote a relative relationship for convenience. Each of the electrodes 3A, 3B, and 3C are configured such that the potential thereof can be controlled. A charged particle beam emitted from a beam source (not shown) passes along the optical axis J in the direction indicated by an arrow. That is, the optical axis J extends in a direction in which the charged particle beam passes.

In the present invention, the potential of each of the three electrodes 3A, 3B, and 3C can be controlled. For example, the first surface and the second surface have a first potential, the third surface and the fourth surface have a second potential, and the fifth surface and the sixth surface have a third potential. To be specific, a so-called einzel electrostatic lens is formed by applying a negative static voltage to the electrode 3B while maintaining the potential of the electrodes 3A and 3C at the ground potential. In the present invention, the term “einzel electrostatic lens” refers to an electrostatic lens in which a plurality of (typically, three) electrodes are arranged with predetermined intervals therebetween and in which the potential of outermost electrodes are maintained at the ground potential and a positive or negative potential is applied to other electrodes. When three electrodes are used, the first and the third electrodes from the incident side of a charged particle beam are maintained at the ground potential, and a positive or negative potential is applied to the second electrode.

The three electrodes have the following surfaces, each having the optical axis J as a normal line. The electrode 3A has a first surface 5 and a second surface 6; the electrode 3B has a third surface 7 and a fourth surface 8; and the electrode 3C has a fifth surface 9 and a sixth surface 10. As illustrated in FIG. 1A, the second surface 6 and the third surface 7 face each other, and the fourth surface 8 and the fifth surface 9 face each other. Here, the terms “first” to “sixth” surfaces are used for convenience of representing the relationship between one surface (typically the front surface) of each electrode and the other surface (typically the back surface) opposite to the one surface.

Each of the three electrodes has a through-hole 2. The through-hole extends through each of the electrode in the thickness direction. A charged particle beam can pass through the through-hole.

As illustrated in FIG. 1B, the through-hole 2 has a circular shape at the first surface 5, which is the top surface of the electrode 3A. Likewise, when an opening cross section is defined as a cross section of the through -hole 2 taken along a plane having the optical axis J as a normal line, the through-hole 2 has a circular shape at any cross section of the electrode in the thickness direction. However, an error of the circular shape from a perfect circle varies.

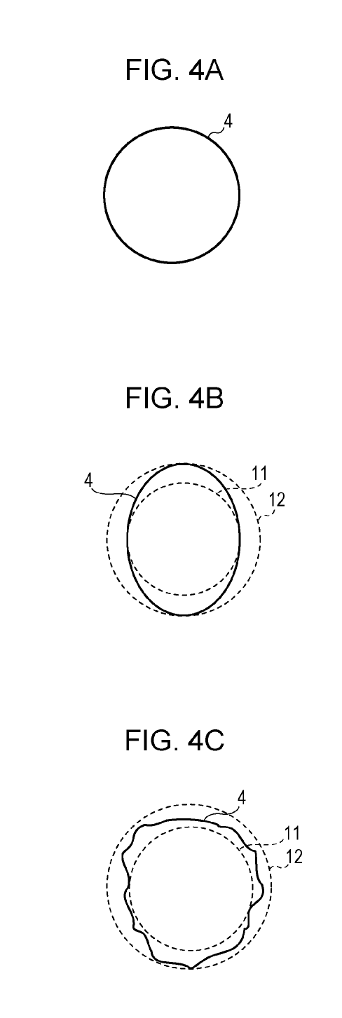

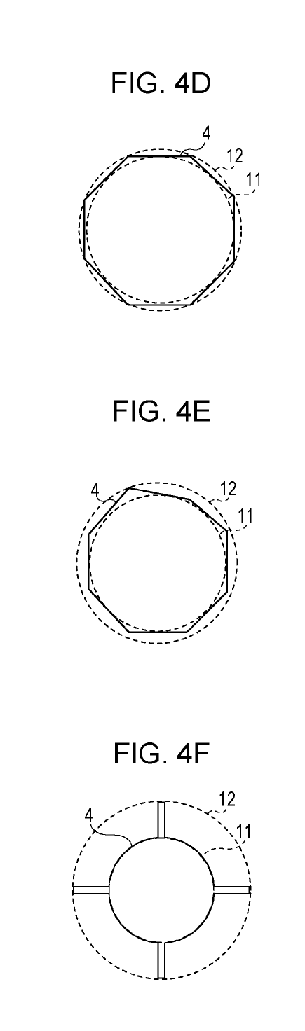

Referring to FIGS. 4A to 4F, the definition of the circularity of an opening cross section, which is necessary for describing a charged particle beam lens according to the present invention, will be described. An electrostatic field that generates a lens effect of an electrostatic charged particle beam lens is formed by the opening cross section. In particular, because astigmatism and higher order aberrations are generated due to rotational asymmetry around the optical axis J, deviation from a perfect circle is an important index.

FIG. 4A illustrates an opening cross section 4 having an ideally circular shape. FIG. 4B illustrates an opening cross section 4 having an elliptical shape. The following index is defined as a measure of a shape error that influences the astigmatism and higher order aberrations of a charged particle beam lens according to the present invention. The opening cross section 4 illustrated in FIG. 4B, which has an elliptical shape, is disposed between two concentric circles so as to be in contact with the concentric circles. The inner circle will be referred to as an incircle 11, and the outer circle will be referred to as a circumcircle 12. Among many combinations of such concentric circles that can be drawn around different centers, a pair of an incircle and a circumcircle between which the difference in the radii thereof is the smallest are selected. The circularity is defined as a half the difference in the radii of the incircle and the circumcircle that are selected in this way. For the opening cross section 4 having a perfectly circular shape as illustrated in FIG. 4A, the circularity is zero because the circumcircle and the incircle coincide with each other.

As illustrated in FIG. 4C, the circularity is defined in a similar manner for any shapes other than ellipse.

The ideal shape in terms of design may not be a circular shape but a polygonal shape as illustrated in FIG. 4D. (An octagonal shape used as an example in the following description.) In this case, the circularity, the representative radius (described below), and the representative diameter (described below) are defined by the following method. That is, deviation of symmetry from an ideal octagon and the size of the through-hole can be compared by defining the circularity, the representative radius, and the representative diameter. FIG. 4D illustrates the circumcircle 12 and the incircle 11 of an ideal octagon. In the case of an octagon, the circularity is equal to or larger than zero even in an ideal state. FIG. 4E illustrates the circumcircle 12 and the incircle 11 of an octagon that has a shape error and that is deviated from a regular octagon. Therefore, the circularity in the case of FIG. 4E is larger than that of FIG. 4D, which is the case of a regular octagon.

The circularity can be defined by actually measuring the sectional shape. The sectional shape can be calculated by dividing the perimeter into a sufficiently large number of segments and obtaining the circumcircle 12 and the incircle 11 through image processing.

The representative diameter and the representative radius are defined as follows. For each of various opening cross sections 4 illustrated in FIGS. 4A to 4F, the coordinates of the curve are measured at sufficiently large numbers of points relative to the perimeter, and the measurement points can be geometrically curve-fitted to an ideal circle by using a regression analysis. The representative diameter and the representative radius are defined as the diameter and the radius of the obtained circle. For example, FIG. 4F illustrates an opening cross section 4 most parts of which are circular and the remaining parts have protruding shapes that protrude inward or outward from a perimeter. Even in this case, the representative diameter and the representative radius can be obtained by using the method described above. When such a circle is obtained, the circumcircle 12 and the incircle 11 are defined by drawing circles that are concentric with the circle that has been obtained by performing geometric fitting.

On the basis of the definition described above, the circularity, the representative radius, and the representative diameter are defined for an arbitrary opening cross section. Hereinafter, a circle is used as the ideal shape of an opening cross section. However, the ideal shape may be an octagon or any other curve. Also in such cases, the circularity, the representative radius, the representative diameter can be defined and used in the present invention.

The circularities of opening cross sections at the first to sixth surfaces according to the present embodiment has the following relationship:

E1, E6>E2, E3, E4, E5 (1),

where E1, E2, E3, E4, E5, and E6 are respectively the circularities of the through-holes 2 in the first surface 5, the second surface 6, the third surface 7, the fourth surface 8, the fifth surface 9, and the sixth surface 10.

Depending on the polarity of the charge of a charged particle beam and the potentials of the electrode 3A and the electrode 3C relative to the potential of the electrode 3B, the circularities may have the following relationship.

When charged particles have a negative charge,

E2<E3 if Va<Vb (2)

E2>E3 if Va>Vb (3)

E4>E5 if Vb>Vc (4)

E4<E5 if Vb<Vc (5),

where Va, Vb, Vc are respectively the potentials of the electrodes 3A, 3B, and 3C.

When charged particles have a positive charge,

E2>E3 if Va<Vb (6)

E2<E3 if Va>Vb (7)

E4<E5 if Vb>Vc (8)

E4>E5 if Vb<Vc (9).

Here, an electrode having a higher voltage will be referred to as an anode (positive electrode), and an electrode having a lower voltage will be referred to as a cathode (negative electrode). When the anode and the cathode in the set of the electrode 3A and the electrode 3B and the anode and the cathode in the set of the electrode 3B and the electrode 3C and the polarity of the charged particle beam are compared with each other, the circularity at a surface that has a polarity the same as that of the charge of be beam has a better circularity (having a smaller value, which means that the shape is closer to a perfect circle).

In the present embodiment, when the potentials have the following relationship, the circularities may have the following relationship.

When charged particles has a negative charge,

E3<E4 if Va=Vc=0 and Vb<0 (10).

When charged particles has a positive charge,

E3<E4 if Va=Vc=0V and Vb>0 (11).

If these relationships exist, the charged particle beam lens has a small aberration even when all the circularities of the through-holes formed in the three electrodes are not necessarily good values. This is because the sensitivity of the aberration of the charged particle beam lens to an error in the circularity (in other words, influence of deviation in shape from a perfect circle on the aberration) differs between the first to sixth surfaces 5 to 10.

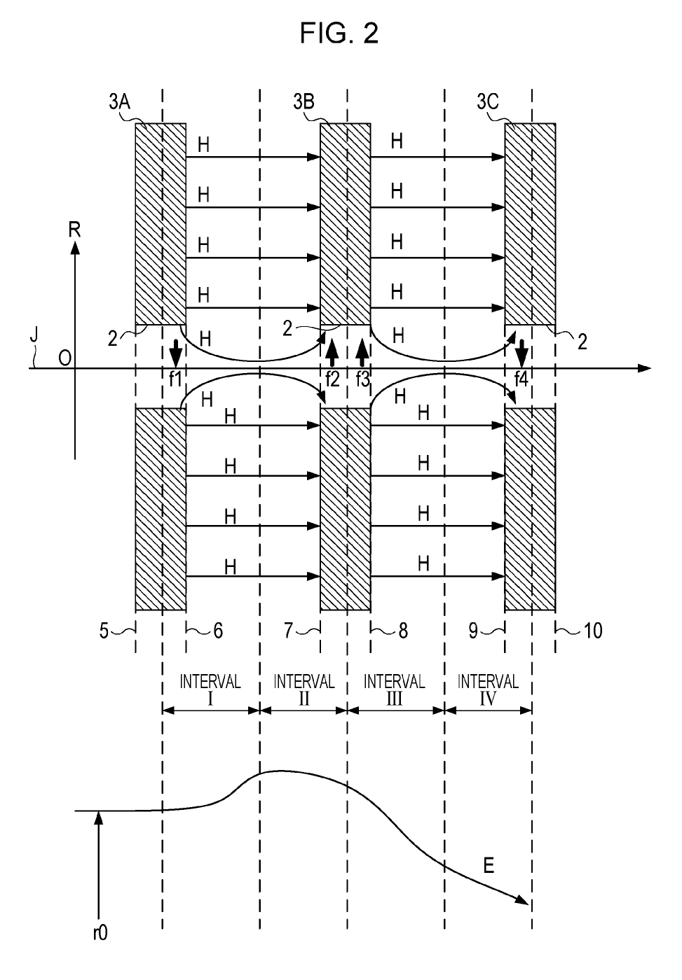

Next, referring to FIG. 2, the reason why the relationships of expression (1) to (11) are appropriate will be described. These relationships occur due to mechanisms with which an electrostatic charged particle beam lens converges a charged particle beam. In FIG. 2, an R-axis extends in the radial direction of the lens, a J-axis extends in the optical axis direction, and “O” denotes the origin. Thus, FIG. 2 corresponds to a sectional view in which the charged particle beam lens of FIG. 1A is rotated by 90 degrees. Here, a case where the potential of the electrodes 3A and 3C are maintained at the ground potential and a negative potential is applied to the electrode 3B will be described. A charged particle beam has a negative charge.

Electric flux lines generated in this structure are illustrated by solid-line arrows H. The mid-planes of the three electrodes 3A, 3B, and 3C in the J direction and the mid-planes of spaces between the three electrodes are illustrated by broken lines I. Intervals between broken lines will be referred to as an interval I, an interval II, an interval III, an interval IV. It is assumed that an interval on the origin O side of the interval I and an interval in which J is larger than that in the interval IV are not provided with a potential, because the electrodes 2A and 2C at the ground potential.

The directions of electric fields in the interval I, the interval II, the interval III, and the interval IV in a region where R>0 are respectively indicated by arrows f1, f2, f3, and f4. The directions of the electric fields in the interval I, the interval II, the interval III, and the interval IV are respectively negative, positive, positive, and negative. Therefore, the path of a charged particle beam that passes an image height r0 is as indicated by arrow E. That is, the charged particle beam is diverged in the interval I, converged in the interval II, converged in the interval III, and diverged in the interval IV. This is optically equivalent to a concave lens, a convex lens, a convex lens, and a concave lens that are arranged in the J-axis direction.

The charged particle beam is converged for the following two reasons. A first reason is that, because a stronger force is applied to the charged particle beam at a larger image height, the effect of convergence in the interval II and the interval III is larger than the effect of divergence in the interval I and the interval IV. A second reason is that the charged particle beam travels in the interval II for a time longer than that in the interval I and travels in the interval III for a time longer than that in the interval IV. Because a change in momentum is equal to an impulse, a larger effect occurs on the electron beam in the intervals that take a longer time for the electron beam to travel.

A convergence effect is generated for the reasons described above. An electric field that produces the lens effect are formed by the cross sectional shapes at the positions of the set the second surface 6 and the third surface 7 and the cross sectional shapes at the positions of the set of the fourth surface 8 and the fifth surface 9, which face each other in the intervals I to IV. If the circularities of the cross sectional shapes of these facing surfaces are bad (i.e. the values of the circularities are large), the rotational symmetry of the electric field is broken, so that astigmatism or higher order aberrations may occur. The relationship of expression (1) according to the present invention is derived from this reason. Each of the first surface 5 and the sixth surface 10 does not have a surface facing thereto. Therefore, regardless of the polarity of the charge of the charged particle beam or the potentials of the electrodes 3A, 3B, and 3C, the influences of these surfaces on the convergence effect of the lens are always smaller than those of the second to fifth surfaces.

The influences of the set of the second surface 6 and the third surface 7 and the set of the fourth surface 8 and the fifth surface 9, which face each other, on the aberration are as follows. In these sets of facing surfaces, a pair of a convex lens effect and a concave lens effect is produced. As described above, the concave lens effect is larger than the convex lens effect. The surface at which the concave lens effect is produced is a surface of the set at which the polarity of surface is the same as the polarity of the charge of the charged particle beam. In this example, the third surface 7 and the fourth surface 8 are such surfaces.

Here, even when a positive potential is applied to the electrode 3B, a charged particle beam having a negative charge is converged. In this case, the interval I, the interval II, the interval III, and the interval IV are equivalent to an arrangement of a convex lens, a concave lens, a concave lens, and a convex lens. In this case, the sectional shapes at the second surface 6 and the fifth surface 9 has a larger influence on the aberration than the sectional shapes at the third surface 7 and the fourth surface 8.

When the charge of the charged particle beam positive, the relationship is opposite to the one described above. But the principle is the same. That is, when a negative potential is applied to the electrode 3B, the sectional shapes at the second surface 6 and the fifth surface 9 have a large influence on the aberration. When a positive potential is applied to the electrode 3B, the sectional shapes at the third surface 7 and the fourth surface 8 have a larger influence on the aberration. The phrase “potential is applied” means that a voltage having a predetermined polarity is provided (applied).

As a result, on the basis of the principle described above, when the relationships represented by expressions (2) to (9) are all satisfied, the aberration can be reduced even if an electrode including a front surface having an opening cross section having a bad circularity is used.

Next, the relationship represented by expressions (10) and (11) will be described. When the polarity of a charged particle beam is the same as that of the electrode 3B, the lens has an average speed in the intervals I to IV that is lower than that of a region outside these intervals. Therefore, the lens effect relative to the strength of an electric field is large, so that the lens can have a large convergence effect with the same withstand voltage. When the relationship represented by expressions (10) and (11) are satisfied, the intervals are equivalent to an arrangement of a convex lens, a concave lens, a concave lens, and a convex lens. In th interval II, the charged particle beam passes an image height larger than that of the interval III due to the influence of a convex lens of the interval I. In contrast, in the interval III, the image height is larger than that of interval II due to the influence of the interval II. The higher the image height, a larger force is applied to the charged particle beam. Thus, the interval II produces a larger convergence effect. Therefore, when the third surface 7 and the fourth surface 8 are compared with each other, if the circularity of the third surface 7 is better than that of the fourth surface 8, the aberration can be reduced as compared with the opposite case.

For the reasons described above, when the relationships represented by expressions (1) to (11) are satisfied, the aberration of the charged particle beam lens can be reduced even if the circularities of the through-holes formed in the three electrodes do not have good values over the entire length of the through-hole.

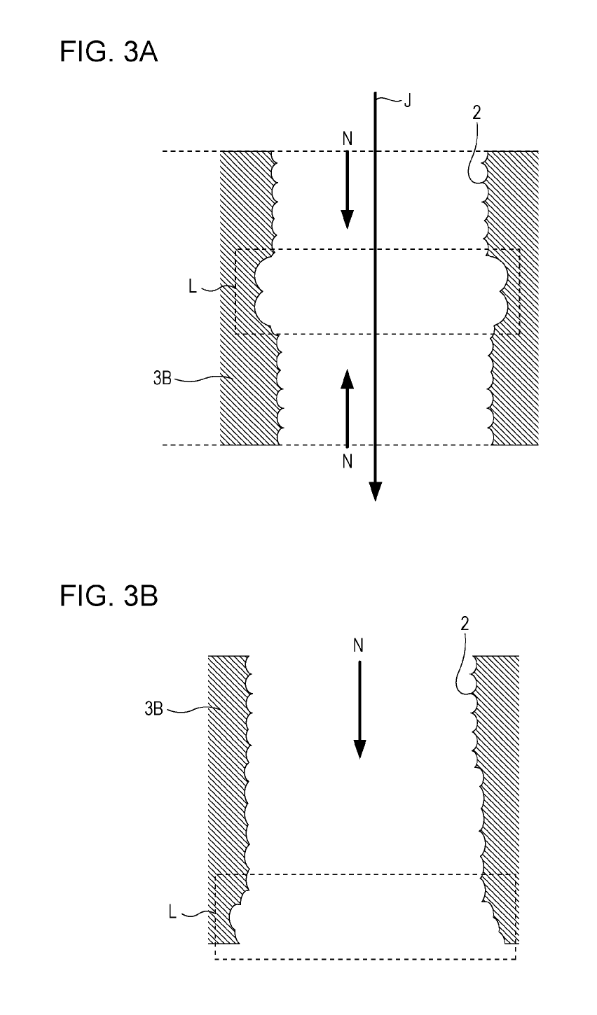

Next, a problem in that fabrication errors in the opening cross sections in the front and back surfaces of the present embodiment may become different from each other will be described. The electrodes 3A, 3B, 3C are made form monochrystalline silicon. The diameter of the through-hole 2 is 30 micrometers, and the thickness of an electrode is 100 micrometers. In the present embodiment, for example, when a charged particle beam is an electron beam, the electron beam can be converged by applying a voltage in the range of −3 to −4 kV to the electrode 3B and maintaining the electrodes 3A and 3C at the ground potential. FIGS. 3A and 3B are enlarged sectional views of the vicinity of the through-hole 2 formed in an electrode illustrated in FIG. 1A. The circularities of the first to sixth surfaces (E1 to E6) are respectively as follows: E1=150 nm, E2=30 nm, E3=20 nm, E4=25 nm, E5=30 nm, E6=150 nm. As described below, by using a semiconductor manufacturing process and deep dry etching of silicon, a through-hole having a diameter of several tens of micrometers diameter can be formed with a circularity in the order of several tens to several hundreds of nanometers.

FIG. 3A illustrates a sectional shape that is formed by performing deep dry etching of a monocrystalline silicon substrate so that a through-hole extends through the substrate in the direction of arrow N. In a deep dry etching process, etching is performed while alternately supplying an etching gas and a shielding gas. Therefore, as illustrated in FIG. 3A, a small asperity called a scallop is formed on a side surface. As etching progresses, error factors that influence the asperity, such as supply and exhaust of the etching gas and the shielding gas and heat due to chemical reaction, increase. Therefore, the depth and pitch of the asperity is changed depending the position, and thereby the circularity may become worse. Moreover, it is known that, just before an opening extends through the substrate, the path of the etching gas is bent due to the presence of an interface in a direction in which the through-hole is being formed, and thereby a phenomenon called “notching”, with which the opening is widened as shown by a region surrounded by broken line L, occurs. Due to these effects, the circularity of such a through-hole becomes worse in the direction of arrow N. Therefore, the circularity of the region surrounded by broken line L is the worst. When such a through-hole is used as the electrode, the aberration of the lens may be increased due to the bad circularity of the opening cross section in the region surrounded by broken line L.

As described above, in order to control the circularities of the sectional shapes of the through-hole at any positions of the through-hole, it is necessary to control the conditions of the etching very strictly an in a very small range. Depending on the target value of the circularity, the fabrication itself may become impossible.

FIG. 3A illustrates an example in which both surfaces of the substrate are exposed and etching is performed by forming etching masks on both surfaces. In this example, the circularities at the front and back surfaces can be made substantially the same. However, it is necessary to perform lithography twice. With the process illustrated in FIG. 3B, in which a through-hole is formed by etching or cutting, a smallest unit step is a step of forming the through-hole in one direction. Therefore, when it is necessary to make the circularities the same, the number of steps increases as in the example illustrated in FIG. 3A. As another example of a process with which the circularities at the front and back surfaces can be made the same, for example, the through-hole at the back surface having a bad circularity may be additionally processed to improve the circularity at the back surface after performing the etching illustrated in FIG. 3B. Thus, if the number of steps is allowed to be increased from that of the unit step illustrated in FIG. 3B, the circularities at the front and back outermost surfaces can be both improved.

However, if the process of FIG. 3B can be used in spite of the bad circularity on one of the surfaces, the number of steps is small and thereby the yield is improved and manufacturing can be performed at low cost. Therefore, if the number of electrodes that can be formed with the simple step illustrated in FIG. 3B can be increased, the const of an electrostatic charged particle beam lens can be reduced.

Among the electrodes 3A, 3B, and 3C of the charged particle beam lens according to the present embodiment, which is illustrated in FIG. 1A, only the electrode 3B is made by etching a substrate in two directions as illustrated in FIG. 3A. The electrode 3A is oriented such that the direction of arrow N in the through-hole 2 in FIG. 3B coincides with the direction from the second surface 6 toward the third surface 5 in FIG. 1A. The electrode 3C is oriented such that the direction arrow N in the through-hole 2 in FIG. 3B coincides with the direction from the fifth surface 9 toward the sixth surface 10 in FIG. 1A.

By doing so, the relationship represented by expression (1) is satisfied. Therefore, even when the through-hole in only one electrode is manufactured by the process illustrated in FIG. 3A, an aberration that is equivalent to that of the case where the through-holes in three electrodes are manufactured by the process illustrated in FIG. 3A can be realized.

Moreover, by improving the circularities of only the corresponding electrodes by using the relationships represented by expressions (2) to (9), increase in the aberration can be restrained while reducing the number of portions for which the highest fabrication precision is required. High fabrication precision may be realized by using a higher-precision lithography apparatus for forming an etching mask or by performing screening through inspection. However, in this case, the number of fabrication steps increases. Therefore, if the number of steps for which such precision is required can be reduced, a lens can be manufactured at low cost.

Furthermore, by using the relationship represented by expression (10), the aberration can be reduced. In the embodiment, by measuring the circularities at the front and back surfaces of a silicon substrate to be used as the electrode 3B and by using one of the surfaces having a better circularity as the third surface 7, the aberration can be reduced as compared to the opposite case.

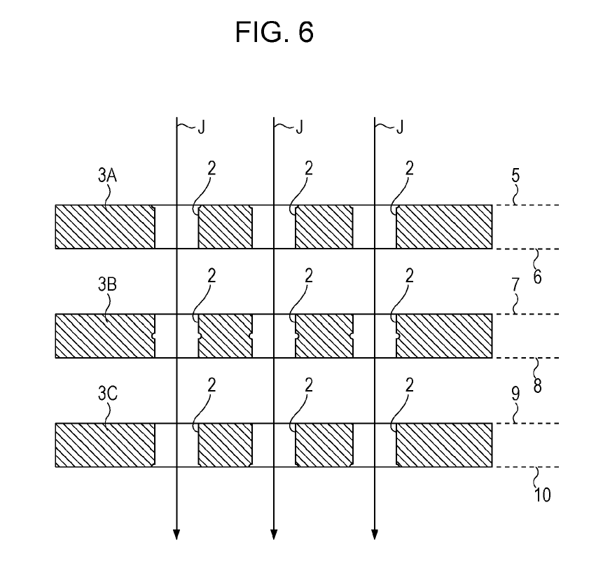

With the present embodiment, a lens array in which a plurality of through-holes are formed as illustrated in FIG. 6 can be formed. In FIG. 6, portions having the same functions as those of FIG. 1A are denoted by the same numerals. Because a lens array has a large array-forming area, in-plane variation in the circularities also has an influence. In particular, when a semiconductor manufacturing process is used to make the lens array, it is necessary to perform high-precision and small-variation processing over a large area, and thereby the cost is considerably increased. Therefore, by disposing the through-holes in the electrodes so that the relationships represented by expressions (1) to (10) are satisfied in accordance with the degree of influence on the aberration, increase in the aberration can be restrained while reducing the number of high-cost steps.

### Second Embodiment

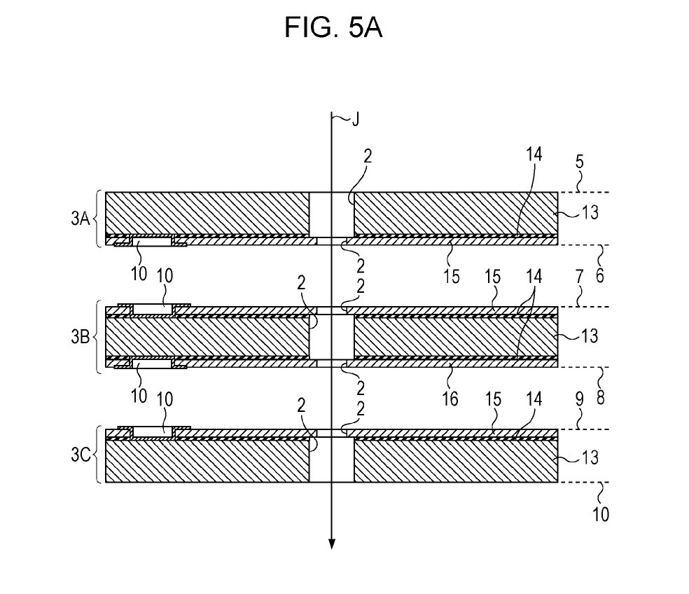

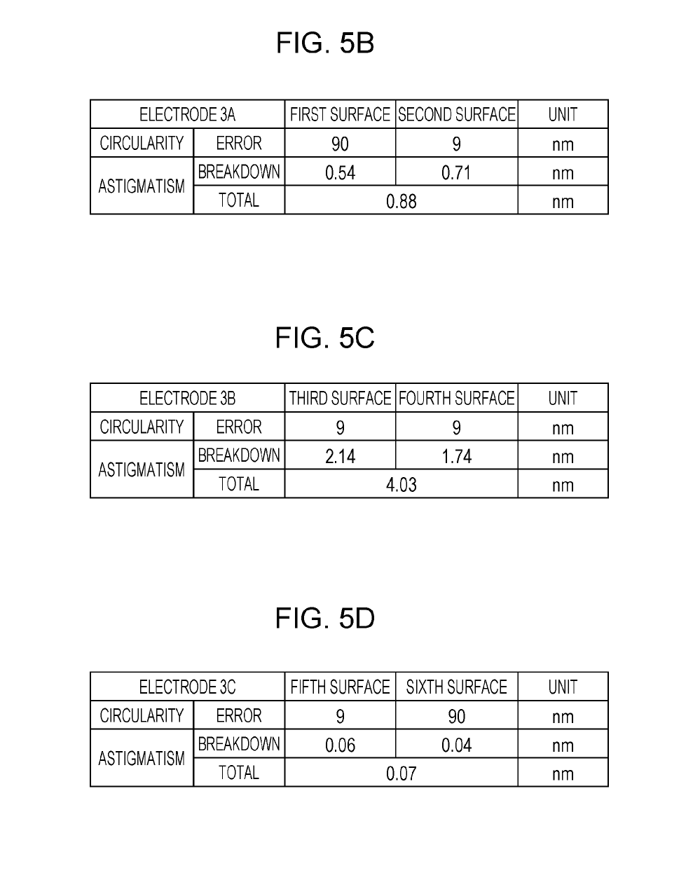

Referring to FIGS. 5A to 6, a second embodiment of the present invention will be described. Portions having the same functions and effects as those of the first embodiment will be denoted by the same numerals and description thereof will be omitted. The present embodiment is different from the first embodiment in that each of the electrodes 3A, 3B, and 3C has a bonded structure.

In the electrodes 3A, 3B, and 3C, a handle layer 13, an oxide film 14, a first device layer 15, and a second device layer 16 are stacked in the thickness direction. In each of the electrodes 3A and 3C, the handle layer 13 having a thickness of 90 micrometers and the first device layer 15 having a thickness of 6 micrometers are bonded to each other with the oxide film 14 therebetween. In the electrode 3A, the first device layer 15 serves as the second surface 6. In the electrode 3C, the first device layer 15 serves as the fifth surface 9. In the electrode 3B, the first device layer 15 having a thickness of 6 micrometers, the handle layer 13 having a thickness of 90 micrometers, and the second device layer 16 having a thickness of 6 micrometers are bonded to each other with the oxide films 14 therebetween. The first device layer 15 serves as the third surface 7 and the second device layer 16 serves as the fourth surface 8. These layers and the film are all made from monocrystalline silicon. The diameter of the through-hole 2 in the handle layer 13 is 36 micrometers; and the diameter of the through-hole in the first device layer 15 and the second device layer 16 is 30 micrometers.

The circularities E1 to E6 of the first to sixth surfaces are as follows: E1=90 nm, E2=9 nm, E3=9 nm, E4=9 nm, E5=9 nm, E6=90 nm. As described below, with the present embodiment, a circular cross section that is closer to a perfect circle than that of the first embodiment can be formed because a bonded structure is used. Therefore, with the present embodiment, a through-hole having a diameter of several tens of micrometers can be formed with a circularity in the order of several nanometers.

An electrode pad 10 is made from a metal film that has good adherence to silicon, high conductivity, and resistance to oxidization. For example, multilayer film made from titanium, platinum, and gold can be used. Silicon oxide films are formed at the interfaces. All of the first to sixth surfaces 5 to 10 and the inner walls of the through-hole 2 in the electrodes 3A, 3B, and 3C may be covered by metal films. In this case, a metal such as a platinum metal that is resistant to oxidization or a molybdenum oxide having electroconductivity can be used. The electrodes 3A, 3B, and 3C are disposed so as to be separated from each other with a distance of 400 micrometers therebetween and so as to be parallel to a plane having the optical axis J and a normal line. The electrodes are electrically insulated from each other. The ground potential is applied to the electrodes 3A and 3C, and a potential of −3.7 kV is applied to the electrode 3B, so that the electrodes serve an einzel lens.

Next, a method of manufacturing the present embodiment will be described. The first device layer 15, the handle layer 13, and the second device layer 16 are bonded to each other through the oxide films 14. For each of the electrodes 3A and 3C, a silicon on insulator (SOI) substrate having a device layer with a thickness of 6 micrometers, which is to become the device layer 15, is prepared. Next, the through-hole 2 is formed in the device layer by performing high precision photolithography and dry etching of silicon. Subsequently, the entire substrate is thermally oxidized. Next, the through-hole 2 is formed in a silicon substrate having a thickness of 90 micrometers, which is the same as that of the handle layer 13, by performing photolithography and deep dry etching of silicon. Then, the device layer of the SOI substrate is directly bonded to the silicon substrate, in which the through-hole 2 is formed, through the oxide film 14. Subsequently, by successively removing handle layer and the embedded oxide film layer of the SOI wafer and the thermally oxidized films outside the bonding interfaces of the through-hole 2, each of the electrodes 3A and 3C can be formed. The electrode 2B can be made by using two SOI substrates the same as those used for the electrodes 2A and 2C.

Two SOI (silicon on insulator) substrates having device layers each with a thickness of 6 micrometers, which are to become the first device layer 15 and the second device layer 16, are prepared. Next, the through-hole 2 is formed in the two device layers by performing high precision photolithography and dry etching of silicon. Subsequently, the entire substrate is thermally oxidized. Next, the through-hole 2 is formed in a silicon substrate having a thickness of 90 micrometers, which is the same as that of the handle layer 13, by performing photolithography and deep dry etching of silicon. Then, the device layers of the two SOI substrates are directly bonded to the front and back surface of the silicon substrate, in which the through-hole 2 is formed, through the oxide films 14. Subsequently, by successively removing handle layers and the embedded oxide film layers of the SOI substrates and the thermally oxidized films outside the bonding interfaces of the through-hole 2, the electrodes 3B can be formed.

The three electrodes can be manufactured as described above. When the charged particle beam is an electron beam and the acceleration voltage is 5 keV, the astigmatism of the electrode according to the present embodiment is shown in FIGS. 5B to 5D.

As shown in the tables, the astigmatisms of the electrodes 3A, 3B, and 3C are respectively 0.88 nm, 4.03 nm, and 0.07 nm. Therefore, the astigmatism of the entirety of the lens, which is the root mean square of these values, is 4.13 nm. The astigmatisms of the first to sixth surfaces 5 to 10 when the circularities of these surfaces are all 9 nm, which corresponds to the case of an existing technology, are respectively 0.77 nm, 4.09 nm, and 0.06 nm. Therefore, in this case, the astigmatism of the entirety of the lens is 4.16 nm. Thus, when the relationship represented by expression (1) is satisfied, even if electrodes each having an opening cross section with a circularity of 90 nm at one of the surfaces are used as the electrodes 3A and 3C, the astigmatism can be made substantially the same as that of the case where all the circularity is 9 nm.

Moreover, the relationships represented by expressions (2) to (9) may be used. For example, even if E2 increases from 9 nm to 20 nm, the astigmatism of the entirety of the lens increases only to 4.36 nm. However, if E3 increases from 9 nm to 20 nm, the astigmatism of the entirety of the lens increases to 5.31 nm. Even if E5 increases from 9 nm to 20 nm, the astigmatism of the entirety of the lens increases only to 4.11 nm. However, if E4 increases from 9 nm to 20 nm, the astigmatism of the entirety of the lens increases to 5.31 nm.

High precision etching is performed on the device layer of the SOI substrate, and then the circularity of the through-hole is measured. By selecting an SOI substrate to be bonded for each of the electrodes 3A, 3B, and 3C so that relationships E2>E3 and E4<E5 are satisfied, the yield of the entire lens can be improved. In the design example describe above, when the tolerance is 4.5 nm, even if a device layer of an SOI substrate has an etched opening cross section having a circularity of 20 nm, the SOI substrate can be used as the electrodes 3A and 3C.

Furthermore, the orientation of the electrode 2B can be selected so that the circularities of the device layers bonded to both surfaces of the electrode 2B may satisfy the relationship represented by expression (10).

A bonded structure is used in the present embodiment because an opening cross section can be formed with high precision in a thin layer by etching. Thus, a through-hole having a near-perfect circular shape with a circularity of 9 nm can be formed in a region of the front surface of an electrode having a small thickness of 6 micrometers. The cost of this process of forming a high-precision circular hole is high because a high-precision apparatus needs to be used (for example, a stepper using excimer laser). Therefore, by using the relationships represented by expressions (1) to (11), the number of portions for which such a process is needed can be reduced and the yield can be increased, and thereby a lens having a small aberration can be manufactured at low cost.

In particular, by using a bonded structure in a region in which high precision processes performed, selection of the electrodes can be performed in accordance with actual shape errors after the electrodes have been formed. Therefore, the yield is improved.

### Third Embodiment

Referring to FIG. 6, a third embodiment of the present invention will be described. Portions having the same functions and effects as those of the first embodiment will be denoted by the same numerals and description thereof will be omitted. The present embodiment is different from the first and second embodiments in that the electrode 3A, 3B, and 3C are lens arrays having a plurality of openings.

When a plurality of openings are formed in a large area, control of the yield in manufacturing steps becomes difficult. With the charged particle beam lens according to the present invention, the number of steps of forming a through-hole in the electrodes is small, so that reduction in the yield can be restrained even when forming a large-scale lens array. Therefore, a lens array having a small aberration can be manufactured at low cost.

With the present embodiment, a lens array including a plurality of openings in an electrode having a junction structure can be formed as described in the second embodiment. In this case, because the opening cross section can be formed with high precision due to the junction structure, variation in the circularities of individual lenses of the lens array can be reduced. Because the circularity of an individual lens of the lens array has a random error, it is very difficult to correct the circularity of individual lenses of the lens array. Therefore, because the variation in the circularity of the shape of the opening cross sections can be reduced, a large-scale lens array can be formed.

In the case of a bonded structure, if the alignment precision of bonding is low, displacement of the opening 2 occurs. However, this displacement can be easily corrected because it is a systematic displacement in the entirety of the lens array. Therefore, this structure is appropriate for a large-scale lens array.

### Fourth Embodiment

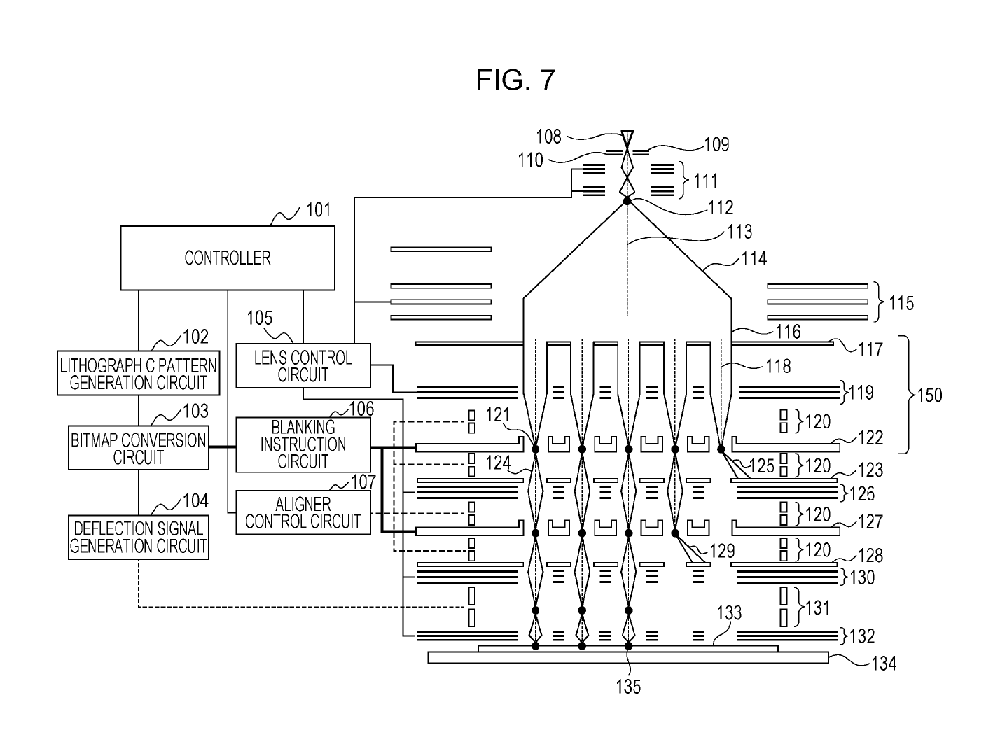

FIG. 7 illustrates a multi-charged-particle-beam exposure apparatus using a charged particle beam lens according to the present invention. The present embodiment is a so-called multi-column type having projection systems individually.

A radiation electron beam that is emitted from an electron source 108 through an anode electrode 110 forms an irradiation optical system crossover 112 due to a crossover adjusting optical system 111.

As the electron source 108, a so-called thermionic electron source using LaB6 or BaO/W (dispenser cathode) is used.

The crossover adjusting optical system 111 includes electrostatic lenses with two tiers. Each of the electric lenses in the first and second tiers is a so-called einzel electrostatic lens that includes three electrodes in which a negative voltage is applied to a middle electrode and the upper and lower electrodes are grounded.

The electron beam, which is spreads with a wide angle from the irradiation optical system crossover 112 is collimated by a collimator lens 115 and an aperture array 117 is irradiated with the collimated beam. The aperture array 117 splits the electron beam into multi-electron beams 118. A focusing lens array 119 individually focuses the multi-electron beams 118 to a blanker array 122.

The focusing lens array 119 is an einzel electrostatic lens array including three electrodes having multiple openings and in which a negative voltage is applied the middle electrode and the upper and lower electrodes are grounded.

The aperture array 117 is disposed at the position of the pupil plane of the focusing lens array 119 (the position of the front focus of the focusing lens array 119) so that the aperture array 117 may serve to define the NA (half-angle of focus).

The blanker array 122, which is a device having an independent deflection electrode, performs ON/OFF control of individual beams in accordance with a lithographic pattern on the basis of a blanking signal generated by a lithographic pattern generation circuit 102, a bitmap conversion circuit 103, and a blanking instruction circuit 106.

In a beam-ON state, a voltage is not applied to a deflection electrode of the blanker array 122. In a beam-OFF state, a voltage is applied to a deflection electrode of the blanker array 122, so that the multi-electron beams are deflected. A multi-electron beam 125 that has been deflected by the blanker array 122 is blocked by a stop aperture array 123 disposed behind the blanker array 122, so that the beam is cut off.

In the present embodiment, the blanker array has a two-tier structure in which a second blanker array 127 and a second stop aperture array 128 respectively having structures the same as those of the blanker array 122 and the stop aperture array 123 are disposed in the second tier.

The multi-electron beams that have passed through the blanker array 122 are focused on the second blanker array 127 by a second focusing lens array 126. Then, the multi-electron beams are focused by third and fourth focusing lenses to a wafer 133. As with the focusing lens array 119, each of the second focusing lens array 126, a third focusing lens array 130, and a fourth focusing lens array 132 is an einzel electrostatic lens array.

In particular, the fourth focusing lens array 132 is an objective lens having a reduction ratio of 100. Thus, an electron beam 121 on the intermediate imaging plane of the blanker array 122 (having a spot diameter of 2 micrometers at FWHM) is reduced to 1/100 on a surface of the wafer 133 to form an image of the multi-electron beam having a spot diameter of about 20 nm at FWHM. The fourth focusing lens array 132 is the charged particle beam lens array according to the second embodiment of the present invention.

Scanning of the multi-electron beam on the wafer can be performed by using a deflector 131. The deflector 131 includes four-tier counter electrodes, so that two-stage deflection in the x and y directions can be performed (for simplicity, two-tier deflectors are illustrated as one unit). The deflector 131 is driven in accordance with a signal generated by the deflection signal generation circuit 104.

While a pattern is being formed, the wafer 133 is continuously moved in the X direction by a stage 134. An electron beam 135 on the wafer is deflected in the Y direction by the deflector 131 on the basis of a real-time measurement result obtained by a laser length measuring machine. On/off control of the beam is individually performed by the blanker array 122 and the second blanker array 127 in accordance with the lithographic pattern. Thus, a desired pattern can be formed on the wafer 133 with a high speed.

By using the charged particle beam lens array according to the present invention, focusing having only a small aberration is realized. Therefore, a multi-charged-particle-beam exposure apparatus that can form a fine pattern can be realized. Moreover, the electrode may have a large thickness even if the openings through which multi-beams pass are formed in a large area, so that the number of the multi-beams can be increased. Thus, a charged particles beam exposure apparatus that forms a pattern with a high speed can be realized.

Because a low-cost lens can be used, the exposure apparatus can be provided at low cost.

Moreover, even if the lens array has a large array number and a large opening area, decrease in the yield of the lens array can be restrained and the exposure apparatus can be manufactured at low cost.

The charged particle beam lens array according to the present invention can be used as any of the focusing lens array 119, the second focusing lens array 126, the third focusing lens array 130.

The charged particle beam lens according to the present invention can be used as a charged particle beam lithography apparatus using a single beam instated of using a plurality of beams as illustrated in FIG. 7. Also in this case, by using an inexpensive lens having only a small aberration, a charged particles beam exposure apparatus that forms a fine pattern can be realized at low cost.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-056812, filed Mar. 15, 2011, which is hereby incorporated by reference herein in its entirety.

1. An electrostatic charged particle beam lens comprising:
a first flat plate including a first surface having a normal line extending in a direction of an optical axis and a second surface opposite to the first surface;
a second flat plate including a third surface facing the second surface and a fourth surface opposite to the third surface; and
a third flat plate including a fifth surface facing the fourth surface and a sixth surface opposite to the third surface,
wherein the first flat plate has a first through-hole extending therethrough from the first surface to the second surface,
wherein the second flat plate has a second through-hole extending therethrough from the third surface to the fourth surface,
wherein the third flat plate has a third through-hole extending therethrough from the fifth surface to the sixth surface,
wherein the first through-hole, the second through-hole, and the third through-hole are arranged so that a charged particle beam is allowed to successively pass therethrough, and
wherein, when an opening cross section is defined as a cross section of one of the through-holes taken along a plane perpendicular to the optical axis and an incircle and a circumcircle are respectively defined as two concentric circles having a smaller radius and a larger radius between which the opening cross section is disposed and having the smallest difference in the radii, a difference in the radii of the incircle and the circumcircle of the opening cross section at each of the first surface and the sixth surface is larger than a difference in the radii of the incircle and the circumcircle of the opening cross section at each of the second surface, the third surface, the fourth surface, and the fifth surface.

2. The charged particle beam lens according to claim 1, wherein, when the first surface and the second surface have a first potential, the third surface and the fourth surface have a second potential, the fifth surface and the sixth surface have a third potential, and the charged particle beam has a negative charge, the difference in the radii of the incircle and the circumcircle of the opening cross section of one of the second surface and the third surface having a lower potential is smaller than the difference in the radii of the incircle and the circumcircle of the opening cross section of one of the second surface and the third surface having a higher potential.

3. The charged particle beam lens according to claim 1, wherein, when the first surface and the second surface have a first potential, the third surface and the fourth surface have a second potential, the fifth surface and the sixth surface have a third potential, and the charged particle beam has a negative charge, the difference in the radii of the incircle and the circumcircle of the opening cross section of one of the fourth surface and the fifth surface having a lower potential is smaller than the difference in the radii of the incircle and the circumcircle of the opening cross section of one of the fourth surface and the fifth surface having a higher potential.

4. The charged particle beam lens according to claim 2, wherein the first potential and the third potential are a ground potential, the second potential is a negative potential, and the difference in the radii of the incircle and the circumcircle of the opening cross section of the third surface is smaller than the difference in the radii of the incircle and the circumcircle of the opening cross section of the fourth surface.

5. The charged particle beam lens according to claim 1, wherein, when the first surface and the second surface have a first potential, the third surface and the fourth surface have a second potential, the fifth surface and the sixth surface have a third potential, and the charged particle beam has a positive charge, the difference in the radii of the incircle and the circumcircle of the opening cross section of one of the second surface and the third surface having a higher potential is smaller than the difference in the radii of the incircle and the circumcircle of the opening cross section of one of the second surface and the third surface having a lower potential.

6. The charged particle beam lens according to claim 1, wherein when the first surface and the second surface have a first potential, the third surface and the fourth surface have a second potential, the fifth surface and the sixth surface have a third potential, and the charged particle beam has a positive charge, the difference in the radii of the incircle and the circumcircle of the opening cross section of one of the fourth surface and the fifth surface having a higher potential is smaller than the difference in the radii of the incircle and the circumcircle of the opening cross section of one of the fourth surface and the fifth surface having a lower potential.

7. The charged particle beam lens according to claim 5, wherein the first potential and the third potential are a ground potential, the second potential is a positive potential, and the difference in the radii of the incircle and the circumcircle of the opening cross section of the third surface is smaller than the difference in the radii of the incircle and the circumcircle of the opening cross section of the fourth surface.

8. The charged particle beam lens according to claim 1, wherein at least one of the first flat plate, the second flat plate, and the third flat plate has a stacked or bonded structure.

9. The charged particle beam lens according to claim 1, wherein each of the first flat plate, the second flat plate, and the third flat plate is an array having a plurality of through-holes.

10. An exposure apparatus comprising the charged particle beam lens according to claim 1 and using a charged particle beam.

11. The exposure apparatus according to claim 10 using a plurality of charged particle beams.

12. An electrostatic charged particle beam lens comprising:
a first flat plate including a first surface having a normal line extending in a direction of an optical axis and a second surface opposite to the first surface;
a second flat plate including a third surface facing the second surface and a fourth surface opposite to the third surface; and
a third flat plate including a fifth surface facing the fourth surface and a sixth surface opposite to the third surface,
wherein the first flat plate has a first through-hole extending therethrough from the first surface to the second surface,
wherein the second flat plate has a second through-hole extending therethrough from the third surface to the fourth surface,
wherein the third flat plate has a third through-hole extending therethrough from the fifth surface to the sixth surface,
wherein the first through-hole, the second through-hole, and the third through-hole are arranged so that a charged particle beam is allowed to successively pass therethrough, and
wherein, when an opening cross section is defined as a cross section of one of the through-holes taken along a plane perpendicular to the optical axis, a value of circularity of the opening cross section at each of the first surface and the sixth surface is larger than a value of circularity of the opening cross section at each of the second surface, the third surface, the fourth surface, and the fifth surface.
